(19) United States
(12) Patent Application Publication
(10) Pub. No.: US 2009/0085032 A1
(43) Pub. Date: Apr. 2, 2009

(54) PIXEL STRUCTURE AND FABRICATING METHOD THEREOF

(75) Inventors: Hsien-Kun Chiu, Taoyuan County (TW); Chin-Chuan Lai, Taoyuan County (TW); Shau-Lin Lyu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 12/014,098

(22) Filed: Jan. 15, 2008

(30) Foreign Application Priority Data
Oct. 2, 2007 (TW) 96136901

(51) Int. Cl. H01L 33/00; H01L 21/00

(52) U.S. Cl. 257/59; 438/151; 257/E21.001; 257/E33.001

(57) ABSTRACT

A method of fabricating a pixel structure is provided. First, a semiconductor material layer and a first conductive layer are sequentially formed on a substrate. Next, a first patterned photoresist layer with a fillister is formed on the first conductive layer by a first mask. A semiconductor layer, a drain, and a source are formed by the first patterned photoresist layer. After removing the first patterned photoresist layer, a dielectric material layer covering the source, the drain, and the semiconductor layer is formed. A second conductive layer is formed on the dielectric material layer. Then, a second patterned photoresist layer with a salient is formed on the second conductive layer by a second mask. A gate and a dielectric layer are formed by the second patterned photoresist layer. After removing the second patterned photoresist layer, a pixel electrode electrically connected to the drain is formed above the substrate.

### CROSS-REFERENCE TO RELATED APPLICATION

This application claims the priority benefit of Taiwan application serial no. 96136901, filed on Oct. 2, 2007. The entirety of the above-mentioned patent application is hereby incorporated by reference herein and made a part of this specification.

### BACKGROUND OF THE INVENTION

1. Field of the Invention

The present invention relates to a pixel structure and a fabricating method thereof. More particularly, the present invention relates to a pixel structure of a thin film transistor (TFT) array substrate and a fabricating method thereof.

2. Description of Related Art

In current technology, because liquid crystal displays (LCDs) have the advantages of small volume and light weight, the conventional large-sized cathode ray tube (CRT) displays have been gradually replaced. Therefore, LCDs have been applied in display screens of common electronic products, for example, screens of LCD TVs, personal computers, and mobile phones.

The mainstream of the modern LCD is TFT LCD. TFT LCDs are driven by the TFTs in the pixel structures to operate. Currently, the method of fabricating the pixel structure of TFT LCDs needs four or more mask processes. However, the more the mask processes are performed, the more the cost and time for fabricating TFT LCDs are spent. It leads to a high price and low productivity of TFT LCDs.

### SUMMARY OF THE INVENTION

Accordingly, the present invention is directed to a method of fabricating a pixel structure, so as to reduce the number of times of performing the mask process.

The present invention provides a pixel structure, which has a low manufacturing cost.

The present invention provides a method of fabricating a pixel structure. In the method, first, a substrate is provided, and a semiconductor material layer and a first conductive layer are sequentially formed on the substrate. Next, a first patterned photoresist layer with a fillister is formed on the first conductive layer by using a first mask. The first mask has a first transparent region, a first partially transparent region, and a first opaque region. A portion of the semiconductor material layer and the first conductive layer are removed with the first patterned photoresist layer as a mask, so as to form a semiconductor layer and a patterned first conductive layer. Next, a partial thickness of the first patterned photoresist layer is removed, so as to expose a portion of the patterned first conductive layer. A portion of the patterned first conductive layer is removed with the first patterned photoresist layer as a mask, so as to form a drain and a source. Then, the first patterned photoresist layer is removed. A dielectric material layer is formed on the substrate to cover the source, the drain, and the semiconductor layer. A second conductive layer is formed on the dielectric material layer, and the material of the first conductive layer is different from that of the second conductive layer. A second patterned photoresist layer is formed on the second conductive layer by using a second mask, and the second mask has a second transparent region, a second partially transparent region, and a second opaque region. The second patterned photoresist layer has a salient located above a position between the source and the drain and partially exposes the second conductive layer. A portion of the second conductive layer and a portion of the dielectric material layer are removed with the second patterned photoresist layer as a mask, so as to expose a portion of the drain and to form a patterned second conductive layer and a dielectric layer. A partial thickness of the second patterned photoresist layer is removed, so as to cover the patterned second conductive layer located above a position between the source and the drain. A portion of the patterned second conductive layer is removed with the second patterned photoresist layer as a mask, so as to form a gate. Thereafter, the second patterned photoresist layer is removed. And then, a pixel electrode is formed above the substrate and is electrically connected to the drain.

The present invention further provides a pixel structure, including a substrate, a semiconductor layer, a drain, a source, a dielectric layer, a gate, and a pixel electrode. The semiconductor layer is disposed on the substrate. The drain and the source are disposed on the semiconductor layer. The dielectric layer is disposed on the substrate and covers the semiconductor layer and the source, and exposes a portion of the drain. The gate is disposed on the dielectric layer and located between the source and the drain. The pixel electrode is disposed on the substrate and electrically connected to the drain.

Based on the above, the present invention uses a first mask and a second mask to fabricate a pixel structure. Thus, as compared with conventional art, the present invention can reduce the number of times of performing the mask process, thereby reducing the cost of fabricating the pixel structure.

In order to make the aforementioned and other objects, features and advantages of the present invention comprehensible, embodiments accompanied with figures are described in detail below.

It is to be understood that both the foregoing general description and the following detailed description are exemplary and intended to provide further explanation of the invention as claimed.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIGS. 1A to 1N are schematic views of a method of fabricating a pixel structure according to a first embodiment of the present invention.

FIG. 2 is a schematic cross-sectional view of a pixel structure according to a second embodiment of the present invention.

FIGS. 3A to 3C are schematic views of a method of fabricating the pixel structure of FIG. 2.

FIGS. 4A to 4F are schematic views of a method of fabricating a pixel structure according to a third embodiment of the present invention.

FIG. 5 is a schematic cross-sectional view of a pixel structure according to a fourth embodiment of the present invention.

### DESCRIPTION OF EMBODIMENTS

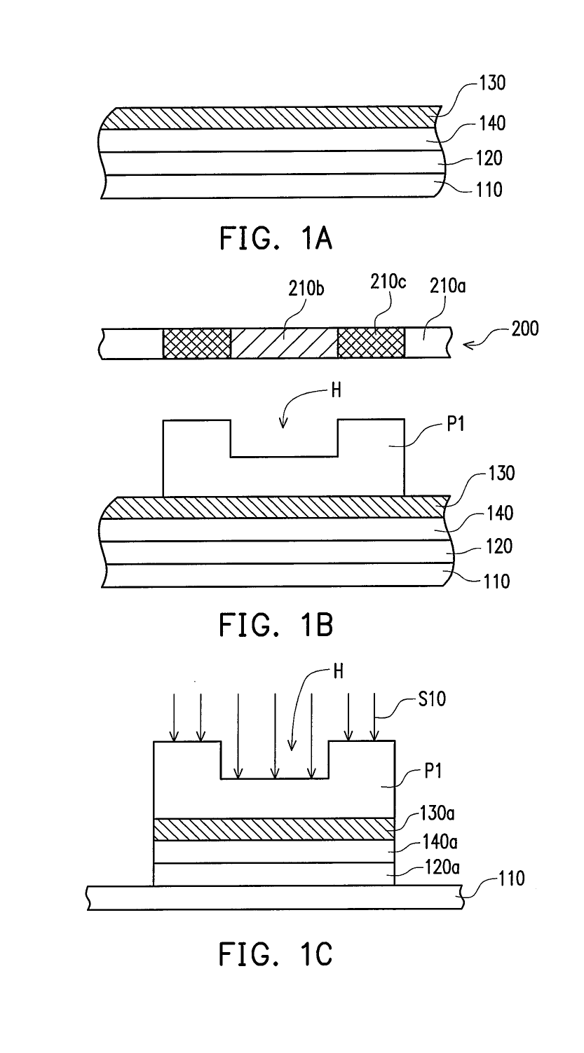

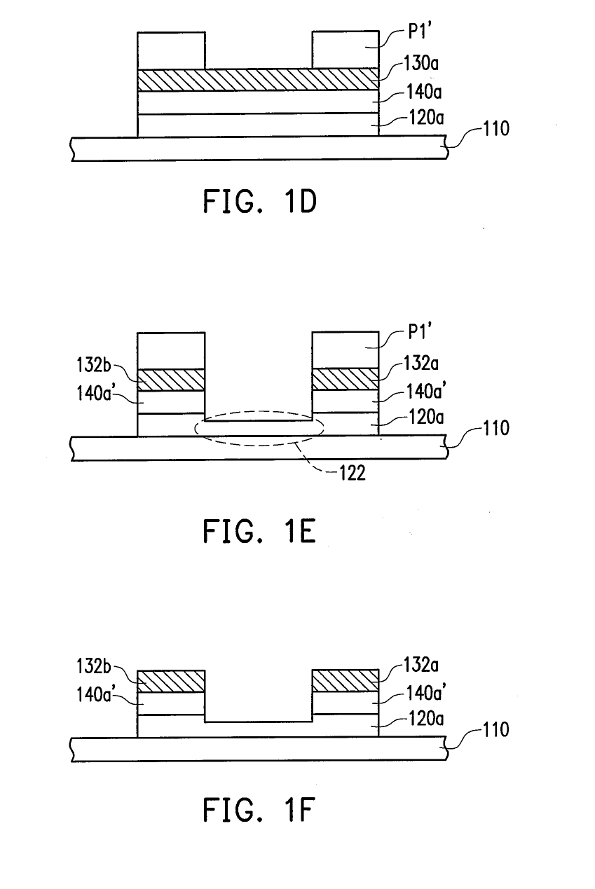

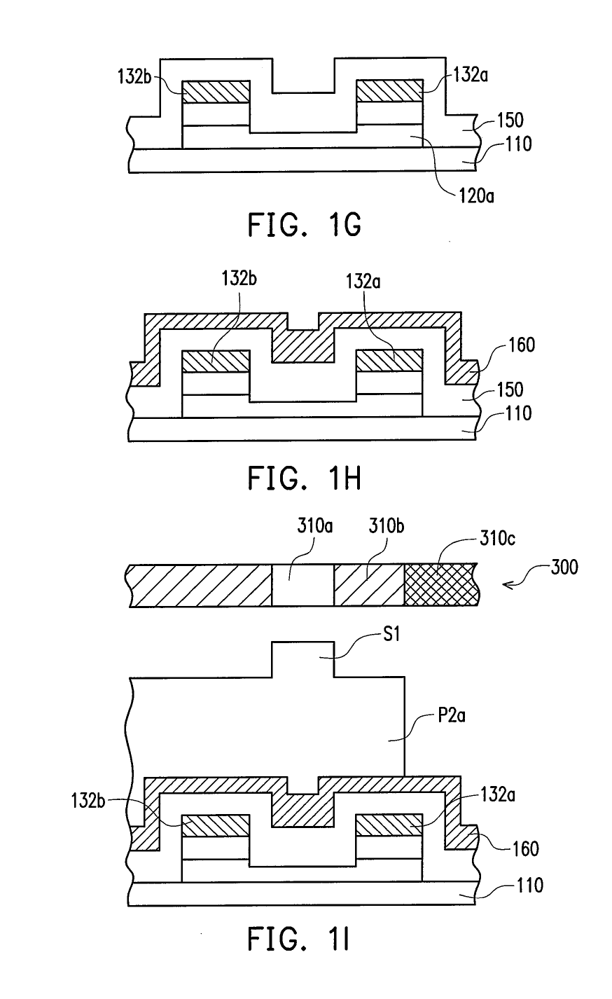

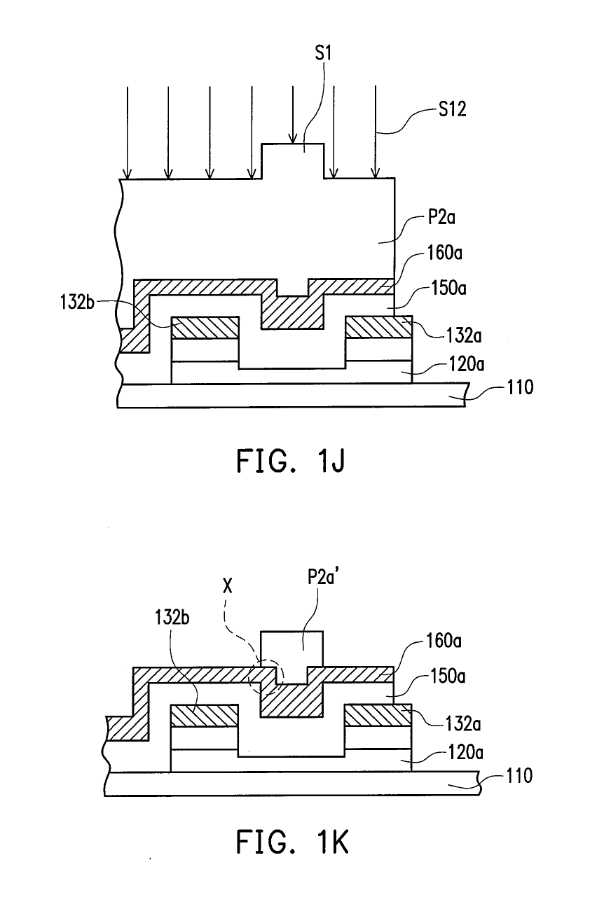

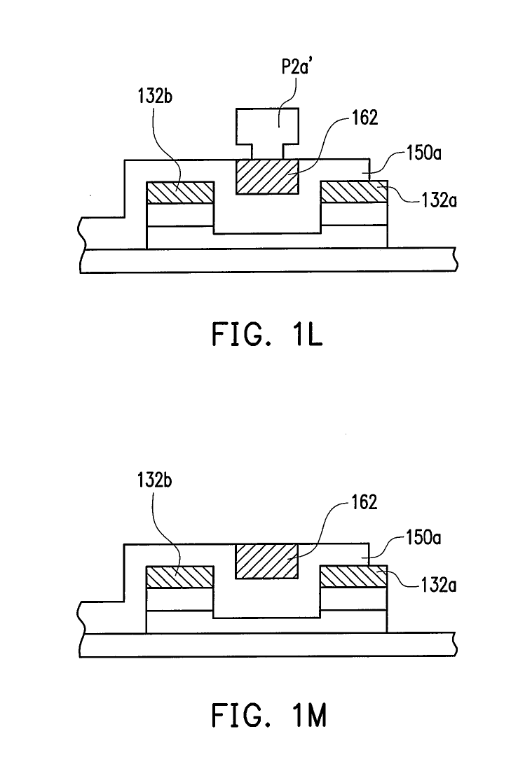

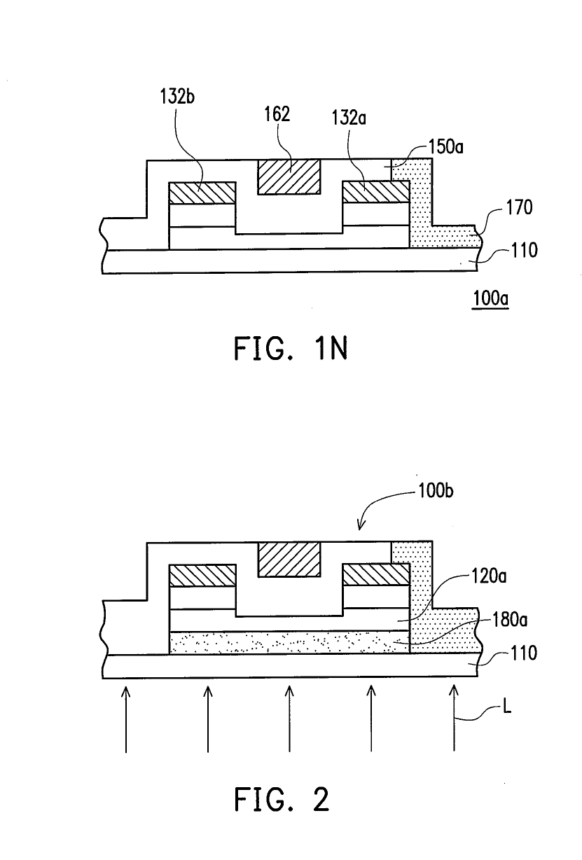

FIGS. 1A to 1N are schematic views of a method of fabricating a pixel structure according to a first embodiment of the present invention. Referring to FIG. 1A, In the method of fabricating a pixel structure of this embodiment. First, a substrate 110 is provided, and a semiconductor material layer 120 and a first conductive layer 130 are sequentially formed on the substrate 110. The material of the semiconductor material layer 120 may be amorphous-silicon (a-Si), polysilicon, or other suitable semiconductor material.

In this embodiment, in order to reduce the impedance between the semiconductor material layer 120 and the first conductive layer 130, an ohmic contact material layer 140 may be formed on the semiconductor material layer 120 before forming the first conductive layer 130. The ohmic contact material layer 140 may be a pentavalent element doped n+ a-Si layer or a trivalent element doped p+ a-Si layer.

Referring to FIG. 1B, next, a first patterned photoresist layer P1 with a fillister H is formed on the first conductive layer 130 by using a first mask 200. The material of the first patterned photoresist layer P1 may be a positive photoresist or a negative photoresist, and the first patterned photoresist layer P1 in FIG. 1B is, for example, a positive photoresist. The first mask 200 has a first transparent region 210a, a first partially transparent region 210b, and a first opaque region 210c. The transmittance of the first partially transparent region 210b is between the transmittances of the first opaque region 210c and the first transparent region 210a. Therefore, the thickness of the first patterned photoresist layer P1 is not uniform, and a fillister H is formed on the first patterned photoresist layer P1 at a position corresponding to the first partially transparent region 210b. Further, the first mask 200 may be a halftone mask or other masks similar to the first mask 200.

Although the material of the first patterned photoresist layer P1 in FIG. 1B is a positive photoresist, the material of the first patterned photoresist layer P1 of this embodiment may also be a negative photoresist. Those of ordinary skill in the art also know that when the material of the first patterned photoresist layer P1 is a negative photoresist, the positions of the first opaque region 210c and the first transparent region 210a of the first mask 200 in FIG. 1B must be exchanged. Therefore, the material of the first patterned photoresist layer P1 and the structure of the first mask 200 in FIG. 1B are not intended to limit the present invention.

Referring to FIGS. 1B and 1C together, next, a portion of the first conductive layer 130, a portion of the semiconductor material layer 120, and a portion of the ohmic contact material layer 140 are removed with the first patterned photoresist layer P1 as a mask, so as to form a patterned first conductive layer 130a, a semiconductor layer 120a, and an ohmic contact layer 140a. The semiconductor layer 120a is disposed on the substrate 110. In detail, the method of removing a portion of the first conductive layer 130, a portion of the semiconductor material layer 120, and a portion of the ohmic contact material layer 140 includes performing an etching process on the first conductive layer 130, the semiconductor material layer 120, and the ohmic contact material layer 140.

Referring to FIGS. 1C and 1D together, next, a partial thickness of the first patterned photoresist layer P1 is removed, such that the first patterned photoresist layer P1 forms a first patterned photoresist layer P1′ (as shown in FIG. 1D) exposing a portion of the patterned first conductive layer 130a. In this embodiment, the method of removing a partial thickness of the first patterned photoresist layer P1 includes performing a plasma ashing process S10 (as shown in FIG. 1C).

As the first patterned photoresist layer P1 has a fillister H, when performing the plasma ashing process S10, the original bottom of the fillister H exposes a portion of the patterned first conductive layer 130a. Further, the method of the plasma ashing process S10 may use O₂ plasma or other suitable ionized gas to remove a partial thickness of the first patterned photoresist layer P1.

Referring to FIGS. 1D and 1E together, after forming the first patterned photoresist layer P1′, a portion of the patterned first conductive layer 130a and the ohmic contact layer 140a are removed with the first patterned photoresist layer P1′ as a mask, so as to form a drain 132a, a source 132b, and an ohmic contact layer 140a′. The drain 132a and the source 132b are disposed on the semiconductor layer 120a, and the ohmic contact layer 140a′ is disposed between the semiconductor layer 120a and the source 132b and between the semiconductor layer 120a and the drain 132a. The edges of the source 132b and the drain 132a may be aligned with the edges of the semiconductor layer 120a and the ohmic contact layer 140a′.

The method of removing a portion of the patterned first conductive layer 130a and a portion of the ohmic contact layer 140a may include performing an etching process on the patterned first conductive layer 130a and the ohmic contact layer 140a. After removing the ohmic contact layer 140a, a partial thickness of the semiconductor layer 120a between the source 132b and the drain 132a may be removed, so as to form a device channel 122. In this manner, it is ensured that the source 132b will not be directly electrically connected to the drain 132a. The method of removing a partial thickness of the semiconductor layer 120a may include performing a back channel etching (BCE) process on the semiconductor layer 120a. And then, the first patterned photoresist layer P1′ is removed, as shown in FIG. 1F.

Referring to FIG. 1G, next, a dielectic material layer 150 is formed on the substrate 110 to cover the source 132b, the drain 132a, and the semiconductor layer 120a. The dielectric material layer 150 may be a silicon nitride layer, a silicon dioxide (SiO₂) layer, or other suitable isolating material layers. Referring to FIG. 1H, a second conductive layer 160 is formed on the dielectric material layer 150. The material of the second conductive layer 160 is different from that of the first conductive layer 130 (referring to FIG. 1B). That is to say, the material of the second conductive layer 160 is different from that of the drain 132a.

Referring to FIG. 1I, next, a second patterned photoresist layer P2a is formed on the second conductive layer 160 by using a second mask 300. The second patterned photoresist layer P2a has a salient S1 located above a position between the source 132b and the drain 132a. In addition, the second patterned photoresist layer P2a exposes a portion of the second conductive layer 160.

The material of the second patterned photoresist layer P2a may be a positive photoresist or a negative photoresist, and the material of the second mask 300 in FIG. 1I is, for example, a positive photoresist. The second mask 300 has a second transparent region 310a, a second partially transparent region 310b, and a second opaque region 310c. The transmittance of the second partially transparent region 310b is between those of the second opaque region 310c and the second transparent region 310a. Therefore, the thickness of the second patterned photoresist layer P2a is not uniform. Hence, the thickness of a portion of the second patterned photoresist layer P2a corresponding to the second transparent region 310a is greater than that of the portion corresponding to the second partially transparent region 310b, thus forming the salient S1 with a greater thickness and corresponding to the second transparent region 310a. In addition, the second mask 300 may be a halftone mask or other masks similar to the second mask 300.

Referring to FIGS. 1I and 1J together, then, a portion of the second conductive layer 160 and a portion of the dielectric material layer 150 are removed with the second patterned photoresist layer P2a as a mask, so as to expose a portion of the drain 132a and form a patterned second conductive layer 160a and a dielectric layer 150a. The dielectric layer 150a is disposed on the substrate 110 and covers the semiconductor layer 120a and the source 132b. It should be noted that the material of the second conductive layer 160 is different from the material of the first conductive layer 130. An etching process with high etching selectivity ratio is adopted on the second conductive layer 160 and the first conductive layer 130.

In the method of removing a portion of the second conductive layer 160 and the dielectric material layer 150, the dielectric layer 150a exposes a portion of the drain 132a and a portion of the semiconductor layer 120a. For example, the dielectric layer 150a in FIG. 1J exposes a side of the drain 132a and a side of the semiconductor layer 120a. However, a portion of the drain 132a and a portion of the semiconductor layer 120a exposed by the dielectric layer 150a in FIG. 1J are merely used to illustrate, but not intended to limit the present invention.

Referring to FIGS. 1J and 1K together, next, a partial thickness of the second patterned photoresist layer P2a is removed, so as to form a second patterned photoresist layer P2a′. The second patterned photoresist layer P2a′ covers the patterned second conductive layer 160a above the position between the source 132b and the drain 132a. In this embodiment, the method of removing a partial thickness of the second patterned photoresist layer P2a may include performing a plasma ashing process S12 to the second patterned photoresist layer P2a. As the second patterned photoresist layer P2a has a salient S1, when performing the plasma ashing process S12, the regions of the second patterned photoresist layer P2a except the salient S1 will be removed while remaining a portion of the second patterned photoresist layer P2a beneath the salient S1. Thus, the second patterned photoresist layer P2a′ is formed.

Referring to FIGS. 1K and 1L, then, a portion of the patterned second conductive layer 160a is removed with the second patterned photoresist layer P2a′ as a mask, so as to form a gate 162 disposed on the dielectric layer 150a and located between the source 132b and the drain 132a. In this embodiment, the method of removing a portion of the patterned second conductive layer 160a includes performing an etching process on the second patterned photoresist layer P2a′.

For example, an etchant may be used in a wet etching process for removing a portion of the patterned second conductive layer 160a. As the material of the first conductive layer 130 is different from that of the second conductive layer 160, i.e., the materials of the patterned second conductive layer 160a and the drain 132a are different, a suitable etchant may be used to remove a portion of the patterned second conductive layer 160a without etching the drain 132a. Furthermore, the wet etching process has the properties of isotropic etching, so a portion of the patterned second conductive layer 160a at the edge of the second patterned photoresist layer P2a′ (position X in FIG. 1K) will be removed. Thus, the surface of the formed gate 162 will be even, as shown in FIG. 1L. Thereafter, the second patterned photoresist layer P2a′ is removed to expose the gate 162, as shown in FIG. 1M.

Referring to FIG. 1N, then, a pixel electrode 170 is formed above the substrate 110. The pixel electrode 170 is electrically connected to the drain 132a. Till now, the fabrication of the pixel structure 100a is substantially completed.

In this embodiment, the pixel electrode 170 may directly cover a portion of the drain 132a to be electrically connected to the drain 132a, as shown in FIG. 1N. Further, the pixel electrode 170 may be made of indium tin oxide (ITO), indium zinc oxide (IZO), or other suitable transparent conductive materials. Additionally, the method of fabricating the pixel electrode 170 includes, for example, the following steps. First a pixel electrode material layer (not shown) covering the dielectric layer 150a, the drain 132a, the gate 162, and the substrate 110 is formed. Next, a photolithography and etching process is performed to the pixel electrode material layer by using a mask (not shown), so as to remove a portion of the pixel electrode material layer. Thus, the pixel electrode 170 is formed.

FIG. 2 is a schematic cross-sectional view of a pixel structure according to a second embodiment of the present invention. Referring to FIG. 2, the pixel structure 100b of this embodiment is similar to the pixel structure 100a (referring to FIG. 1N) of the first embodiment, and the difference therebetween lies in that the pixel structure 100b further includes a light shielding layer 180a. In detail, the light shielding layer 180a is disposed between the semiconductor layer 120a and the substrate 110 of the pixel structure 100a, and the material of the light shielding layer 180a may be an opaque resin or a metal. It can be known that the light shielding layer 180a, characterized by the opaque property, may block a portion of the light rays L from entering the pixel structure 100b through the lower side of the substrate 110, thus preventing the light leakage.

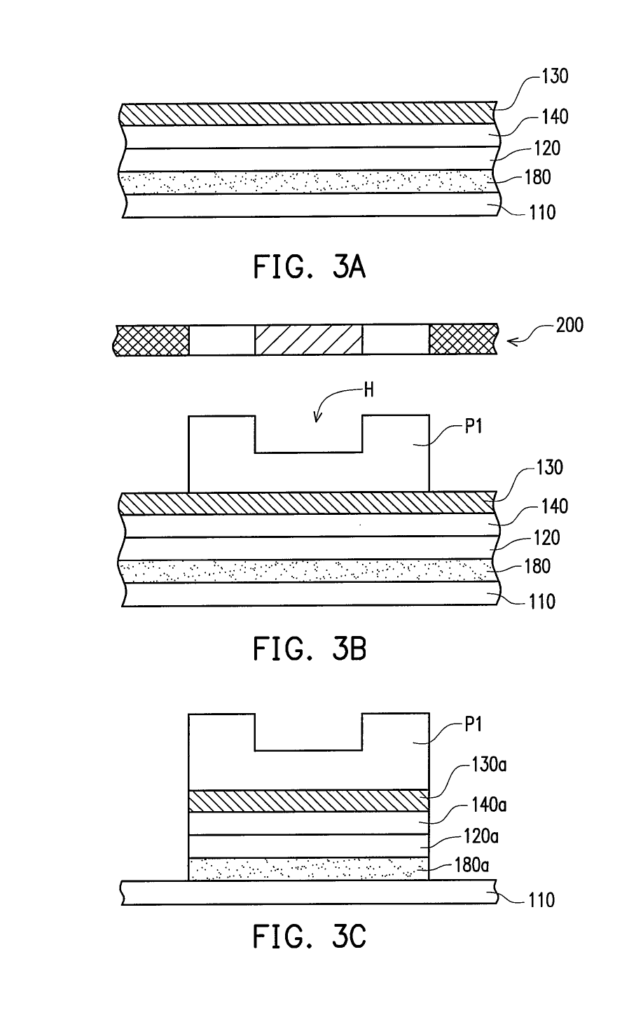

The difference between the pixel structure 100b and the first embodiment is the light shielding layer 180a, and the method of fabricating the pixel structure 100b is similar to that of the first embodiment. Therefore, only the method of fabricating the light shielding layer 180a of this embodiment is described with the accompanying drawings of FIGS. 3A to 3C for illustration. Referring to FIG. 3A, first, a substrate 110 is provided. A light shielding material layer 180, a semiconductor material layer 120, an ohmic contact material layer 140, and a first conductive layer 130 are sequentially formed on the substrate 110. That is, before forming the semiconductor material layer 120, a light shielding material layer 180 is formed on the substrate 110, and the material of the light shielding layer 180a may be an opaque resin or a metal.

Referring to FIG. 3B, then, a first patterned photoresist layer P1 is formed on the first conductive layer 130 by using the first mask 200, in which the first patterned photoresist layer P1 has a fillister H. Referring to FIGS. 3B and 3C together, next, a portion of the semiconductor material layer 120 and a portion of the first conductive layer 130 are removed with the first patterned photoresist layer P1 as a mask, so as to form a semiconductor layer 120a and a patterned first conductive layer 130a.

In the method of removing a portion of the semiconductor material layer 120, a portion of the light shielding material layer 180 is also removed. As a portion of the light shielding material layer 180 and a portion of the semiconductor material layer 120 are removed with the first patterned photoresist layer P1 as a mask, the patterns of the light shielding layer 180a and the semiconductor layer 120a may be the same. After forming the light shielding layer 180a, the steps of fabricating the pixel structure 100b is the same as those of the first embodiment (referring to FIGS. 1C to 1N), so it will not be described herein again.

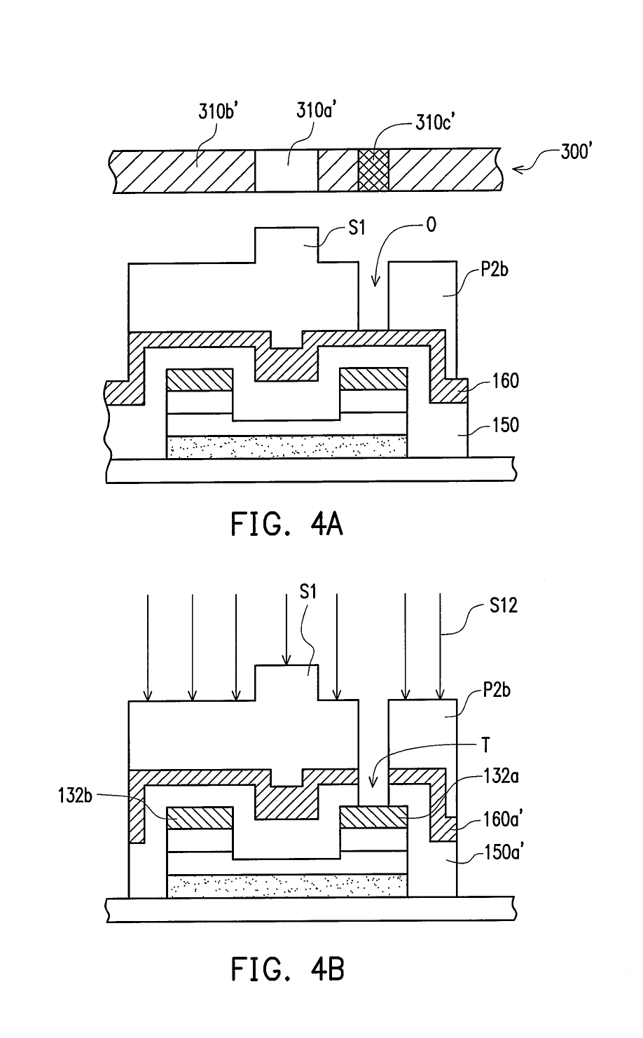

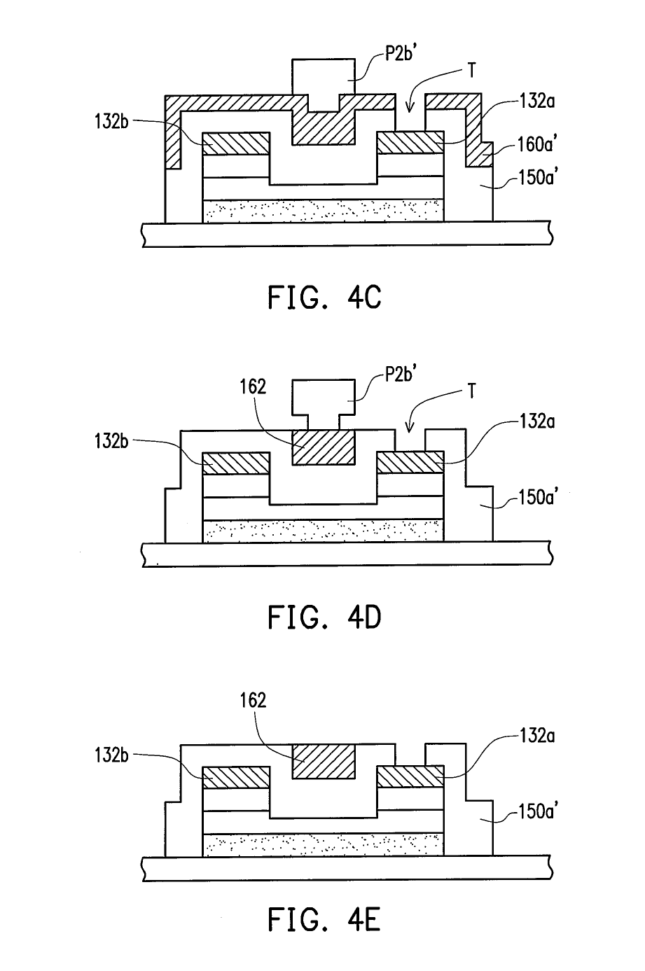

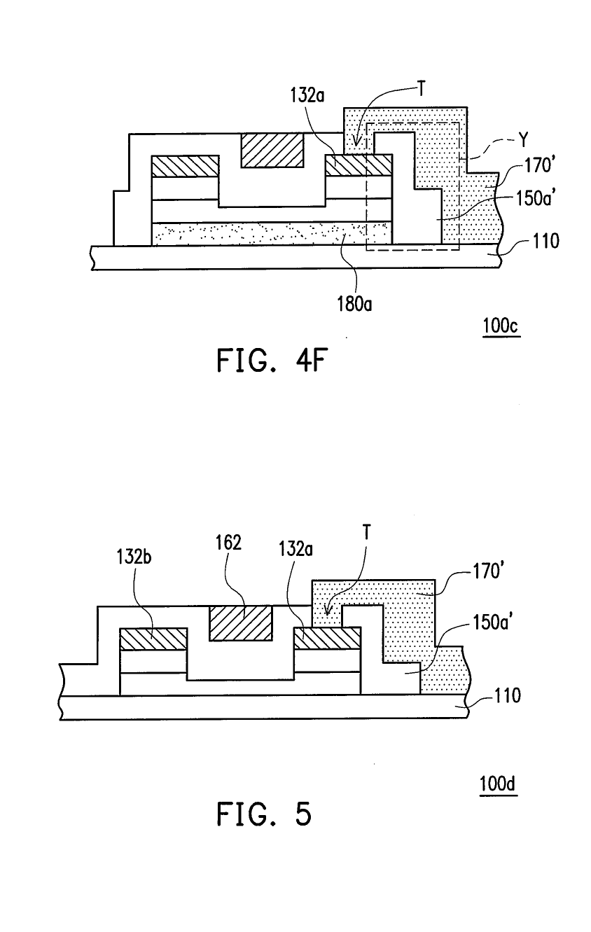

FIGS. 4A to 4F are schematic views of a method of fabricating a pixel structure according to a third embodiment of the present invention, and the difference between this embodiment and the second embodiment merely lies in that the dielectric layer has a contact. Hereinafter, only the structure of the contact and the method of fabricating the contact are described. First, referring to FIG. 4A, after forming the second conductive layer 160 (referring to FIG. 1H), a second patterned photoresist layer P2b is formed on the second conductive layer 160 by using a second mask 300′. The second patterned photoresist layer P2b has a salient S1 and an opening O, and the material of the second patterned photoresist layer P2b is the same as that in the above embodiments.

The second mask 300′ has a second transparent region 310a′, a second partially transparent region 310b′, and a second opaque region 310c′. The salient S1 corresponding to the second transparent region 310a′ and the opening O corresponding to the second opaque region 310c′ are formed based on the different transmittances of the second transparent region 310a′, the second partially transparent region 310b′, and the second opaque region 310c′. Moreover, the second mask 300′ may be a halftone mask or other masks similar to the second mask 300′.

Referring to FIGS. 4A and 4B together, next, a portion of the second conductive layer 160 and a portion of the dielectric material layer 150 are removed with the second patterned photoresist layer P2b as a mask, so as to expose a portion of the drain 132a and form a patterned second conductive layer 160a′ and a dielectric layer 150a′. The dielectric layer 150a′ has a contact T exposing a portion of the drain 132a. In detail, in the method of removing a portion of the second conductive layer 160 and a portion of the dielectric material layer 150, a portion of the second conductive layer 160 and the dielectric material layer 150 at the bottom of the opening O will be removed, thus forming a contact T exposing a portion of the drain 132a.

Referring to FIGS. 4B and 4C together, then, a partial thickness of the second patterned photoresist layer P2b is removed, so as to form a second patterned photoresist layer P2b′ to cover the patterned second conductive layer 160a′ above a position between the source 132b and the drain 132a. In this embodiment, the method of removing a partial thickness of the second patterned photoresist layer P2b includes performing a plasma ashing process S12 to the second patterned photoresist layer P2b′. Thus, the regions of the second patterned photoresist layer P2b except the salient S1 will be removed while remaining a portion of the second patterned photoresist layer P2b beneath the salient S1, thus forming the second patterned photoresist layer P2b′.

Next, a portion of the patterned second conductive layer 160a′ is removed with the second patterned photoresist layer P2b′ as a mask, so as to from a gate 162 (as shown in FIG. 4D). After forming the gate 162, the second patterned photoresist layer P2b′ is removed (as shown in FIG. 4E). Thereafter, a pixel electrode 170′ is formed above the substrate 110, and is disposed on the dielectric layer 150a′ and electrically connected to the drain 132a. Till now, the fabrication of the pixel structure 100c is substantially completed. In this embodiment, a portion of the pixel electrode 170′ may extend into the contact T, thus being electrically connected to the drain 132a. In this manner, the pixel electrode 170′ and the drain 132a are electrically connected.

Furthermore, the dielectric layer 150a′ covers a portion of the light shielding layer 180a, so as to separate the pixel electrode 170′ and the light shielding layer 180a (position Y in FIG. 4F). When the material of the light shielding layer 180a is a metal, the dielectric layer 150a′ electrically insulates the pixel electrode 170′ and the light shielding layer 180a to avoid influencing the normal operation of the pixel structure 100c.

FIG. 5 is a schematic cross-sectional view of a pixel structure according to a fourth embodiment of the present invention. Referring to FIG. 5, the pixel structure 100d of this embodiment is similar to the pixel structure 100c of the fourth embodiment. But, unlike the fourth embodiment, the pixel structure 100d of this embodiment does not include a light shielding layer, as shown in FIG. 5. Moreover, as the pixel structure 100d in FIG. 5 and the fabricating method thereof are similar to those of the above embodiments, so will not be described herein again.

In view of above, the present invention uses a first mask and a second mask to fabricate a pixel structure. Compared with the conventional art, the present invention adopts a reduced number of masks, thus reducing the number of times of performing the mask process. In this manner, the manufacturing cost of the pixel structure is reduced, the fabricating process of the pixel structure is simplified, and further the time required for fabricating the pixel structure is shortened. Furthermore, the pixel structure of the present invention may include a light shielding layer, which can eliminate the occurrence of light leakage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a pixel structure, comprising:
providing a substrate, and forming a semiconductor material layer and a first conductive layer sequentially on the substrate;
forming a first patterned photoresist layer with a fillister on the first conductive layer by using a first mask, wherein the first mask has a first transparent region, a first partially transparent region, and a first opaque region;
removing a portion of the semiconductor material layer and a portion of the first conductive layer with the first patterned photoresist layer as a mask, so as to form a semiconductor layer and a patterned first conductive layer;
removing a partial thickness of the first patterned photoresist layer to expose a portion of the patterned first conductive layer;
removing a portion of the patterned first conductive layer with the first patterned photoresist layer as a mask, so as to form a drain and a source;
removing the first patterned photoresist layer;
forming a dielectric material layer on the substrate to cover the source, the drain, and the semiconductor layer;
forming a second conductive layer on the dielectric material layer;
forming a second patterned photoresist layer on the second conductive layer by using a second mask, wherein the second mask has a second transparent region, a second partially transparent region, and a second opaque region, and the second patterned photoresist layer has a salient located above a position between the source and the drain and partially exposes the second conductive layer;
removing a portion of the second conductive layer and a portion of the dielectric material layer with the second patterned photoresist layer as a mask, so as to expose a portion of the drain and to form a patterned second conductive layer and a dielectric layer;
removing a partial thickness of the second patterned photoresist layer to cover the patterned second conductive layer located above a position between the source and the drain;
removing a portion of the patterned second conductive layer with the second patterned photoresist layer as a mask, so as to form a gate;
removing the second patterned photoresist layer; and
forming a pixel electrode above the substrate, wherein the pixel electrode is electrically connected to the drain.

2. The method of fabricating a pixel structure as claimed in claim 1, before forming the semiconductor material layer, further comprising forming a light shielding material layer on the substrate, and removing a portion of the light shielding material layer in the method of removing the portion of the semiconductor material layer, so as to form a light shielding layer.

3. The method of fabricating a pixel structure as claimed in claim 2, wherein the material of the light shielding layer is an opaque resin.

4. The method of fabricating a pixel structure as claimed in claim 2, wherein the material of the light shielding layer is a metal.

5. The method of fabricating a pixel structure as claimed in claim 1, wherein the first mask is a halftone mask.

6. The method of fabricating a pixel structure as claimed in claim 1, wherein the second mask is a halftone mask.

7. The method of fabricating a pixel structure as claimed in claim 1, wherein in the method of removing the portion of the second conductive layer and the portion of the dielectric material layer, the dielectric layer exposes a portion of the drain and a portion of the semiconductor layer.

8. The method of fabricating a pixel structure as claimed in claim 1, wherein in the method of removing the portion of the second conductive layer and the portion of the dielectric material layer, the dielectric layer has a contact exposing a portion of the drain.

9. The method of fabricating a pixel structure as claimed in claim 1, before forming the first conductive layer, further comprising forming an ohmic contact material layer on the semiconductor material layer, and removing a portion of the ohmic contact material layer before removing the portion of the semiconductor material layer, so as to form an ohmic contact layer.

10. The method of fabricating a pixel structure as claimed in claim 9, after removing the portion of the ohmic contact material layer, further comprising removing a partial thickness of the semiconductor layer between the source and the drain, so as to form a device channel.

11. The method of fabricating a pixel structure as claimed in claim 10, wherein the method of removing a partial thickness of the semiconductor layer between the source and the drain comprises performing a back channel etching process on the semiconductor layer.

12. The method of fabricating a pixel structure as claimed in claim 1, wherein the method of removing a partial thickness of the first patterned photoresist layer comprises performing a plasma ashing process to the first patterned photoresist layer.

13. The method of fabricating a pixel structure as claimed in claim 1, wherein the method of removing a partial thickness of the second patterned photoresist layer comprises performing a plasma ashing process to the second patterned photoresist layer.

14. A pixel structure, comprising:
a substrate;
a semiconductor layer, disposed on the substrate;
a drain, disposed on the semiconductor layer;
a source, disposed on the semiconductor layer;
a dielectric layer, disposed on the substrate, covering the semiconductor layer and the source, and exposing a portion of the drain;
a gate, disposed on the dielectric layer, and located between the source and the drain; and
a pixel electrode, disposed on the substrate, and electrically connected to the drain.

15. The pixel structure as claimed in claim 14, further comprising a light shielding layer disposed between the semiconductor layer and the substrate.

16. The pixel structure as claimed in claim 15, wherein patterns of the light shielding layer and the semiconductor layer are the same.

17. The pixel structure as claimed in claim 15, wherein the material of the light shielding layer is a metal.

18. The pixel structure as claimed in claim 15, wherein the material of the light shielding layer is an opaque resin.

19. The pixel structure as claimed in claim 14, wherein the dielectric layer exposes a portion of the drain and a portion of the semiconductor layer.

20. The pixel structure as claimed in claim 14, wherein the dielectric layer has a contact exposing a portion of the drain.

21. The pixel structure as claimed in claim 14, further comprising an ohmic contact layer disposed between the semiconductor layer and the source and between the semiconductor layer and the drain.
